(19) United States
(12) Patent Application Publication
(10) Pub. No.: US 2026/0173484 A1
(43) Pub. Date: Jun. 18, 2026

(54) DIELECTRIC LAYER OF HIGH VOLTAGE TRANSISTOR AND FABRICATING METHOD OF THE SAME

(71) Applicant: United Semiconductor (Xiamen) Co., Ltd., Xiamen (CN)

(72) Inventors: XIONG ZHANG, Shamen City (CN); Wei-Chun Chang, Taichung City (TW); YUCHUN GUO, Shamen City (CN); You-Di Jhang, New Taipei City (TW); Chin-Chun Huang, Hsinchu County (TW); WEN YI TAN, Xiamen (CN)

(73) Assignee: United Semiconductor (Xiamen) Co., Ltd., Xiamen (CN)

(21) Appl. No.: 19/011,520

(22) Filed: Jan. 6, 2025

(30) Foreign Application Priority Data
Dec. 18, 2024 (CN) 202411874254.6

(51) Int. Cl. H10D 64/27; H10D 64/01

(52) U.S. Cl. CPC H10D 64/516; H10D 64/01

(57) ABSTRACT

A fabricating method of a gate dielectric layer of a high voltage transistor includes providing a semiconductor substrate. Then, a first insulating block and a second insulating block are formed to be embedded in the semiconductor substrate. Later, an insulating layer is formed to be disposed between the first insulating block and the second insulating block. The first insulating block has a first sidewall and a second sidewall. The second sidewall contacts the insulating layer. The first sidewall and the second sidewall are opposite. The first sidewall has a protruding portion. The second sidewall is perpendicular to the top surface of the semiconductor substrate and there is no turning point on the second sidewall.

### BACKGROUND OF THE INVENTION

### 1. Field of the Invention

The present invention relates to a fabricating method of a gate dielectric layer of a high voltage transistor, and more particularly to a fabricating method to avoid concave sharp corners formed on the surface of a gate dielectric layer.

### 2. Description of the Prior Art

Modern integrated circuits include millions or billions of semiconductor components formed on a semiconductor substrate. Integrated circuits include many different types of transistor components. In recent years, the increasing market for radio frequency (RF) components has led to a significant increase in the use of high voltage transistors. For example, high voltage transistors are commonly used in power amplifiers in RF transmission/reception due to their ability to handle high breakdown voltages and high frequencies.

In many applications, various process methods need to be used to maintain the stability of the breakdown voltage of high voltage transistors. However, due to process deviations, the breakdown voltage of high voltage transistors can't be kept stable. Therefore, improvement the stability of high voltage transistors is an important goal of current research in the semiconductor industry.

### SUMMARY OF THE INVENTION

In view of this, the present invention provides a fabricating method of a gate dielectric layer of a high voltage transistor to maintain the stability of the high voltage transistor.

According to a preferred embodiment of the present invention, a fabricating method of a gate dielectric layer of a high voltage transistor includes providing a semiconductor substrate. Next, a first patterned mask is formed to cover the semiconductor substrate, wherein the first patterned mask includes a first opening and a second opening, the first patterned mask includes an oxygen-containing material layer and a first nitrogen-containing material layer stacked from bottom to top. After that, a first etching process is performed to etch the semiconductor substrate to form a first trench and a second trench by using the first patterned mask as a mask. After forming the first trench and the second trench, the first opening and the second opening on the first patterned mask are widened. After widening the first opening and the second opening, a first insulating layer is formed to fill the first trench, the second trench, the first opening and the second opening, wherein the first insulating layer filling the first trench and the first opening is defined as a first insulating block, the first insulating layer filling the second trench and the second opening is defined as a second insulating block, and the semiconductor substrate disposed between the first insulating block and the second insulating block is defined as a middle substrate. Subsequently, the first nitrogen-containing material layer is completely removed to make part of the first insulating block and part of the second insulating block protrude from the oxygen-containing material layer. After removing the first nitrogen-containing material layer, a second nitrogen-containing material layer is formed to cover the first insulating block, the second insulating block and the oxygen-containing material layer. After that, a second patterned mask is formed, wherein the second patterned mask only covers the first insulating block which is away from the middle substrate, and the second insulating block which is away from the middle substrate. The second patterned mask covers part of the semiconductor substrate. The second patterned mask does not cover the middle substrate, the first insulating block which is adjacent to the middle substrate and the second insulating block which is adjacent to the middle substrate. Later, a second etching process is performed to etch the first insulating block, the second insulating block and the middle substrate to form a third trench by using the second patterned mask as a mask. Then, the second patterned mask is removed. Finally, a second insulating layer is formed to fill the third trench.

According to another preferred embodiment of the present invention, a gate dielelctric layer of a high voltage transistor includes a semiconductor substrate. A first insulating block is embedded in the semiconductor substrate. A second insulating block is embedded in the semiconductor substrate. An insulating layer is disposed between the first insulating block and the second insulating block, and the insulating layer physically contacts the first insulating block and the second insulating block. The first insulating block has a first sidewall and a second sidewall, the second sidewall physically contacts the insulating layer, the first sidewall and the second sidewall are opposite, the first sidewall has a protruding portion, and the first sidewall and the second sidewall are asymmetrical

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 8 depict a fabricating method of a gate dielectric layer of a high voltage transistor according to a preferred embodiment of the present invention, wherein:

FIG. 2 is a fabricating stage following FIG. 1;

FIG. 3 is a fabricating stage following FIG. 2;

FIG. 4 is a fabricating stage following FIG. 3;

FIG. 5 is a fabricating stage following FIG. 4;

FIG. 6 is a fabricating stage following FIG. 5;

FIG. 7 is a fabricating stage following FIG. 6; and

FIG. 8 is a fabricating stage following FIG. 7.

FIG. 9 depicts a fabricating method of a high voltage transistor according to a preferred embodiment of the present invention.

FIG. 10 depicts a fabricating method of a high voltage transistor according to another preferred embodiment of the present invention.

FIG. 11 depicts a high voltage transistor according to an exemplary embodiment of the present invention.

### DETAILED DESCRIPTION

FIG. 1 to FIG. 8 depict a fabricating method of a gate dielectric layer of a high voltage transistor according to a preferred embodiment of the present invention.

As shown in FIG. 1, a semiconductor substrate 10 is provided. The semiconductor substrate 10 includes a silicon substrate, a germanium substrate, a gallium arsenide substrate, a silicon germanium substrate, an indium phosphide substrate, a gallium nitride substrate, a silicon carbide substrate or a silicon on insulator substrate. Then, a doping well 12 is formed and embedded in the semiconductor substrate 10. Later, an oxygen-containing material layer 14 is formed, and then a first nitrogen-containing material layer 16 is formed to cover the semiconductor substrate 10. The oxygen-containing material layer 14 and the first nitrogen-containing material layer 16 are stacked from bottom to top in a listed sequence. Next, a patterned composite photoresist layer (not shown) is formed to cover the first nitrogen-containing material layer 16 and the oxygen-containing material layer 14. After that, the first nitrogen-containing material layer 16 and the oxygen-containing material layer 14 are etched to form a first patterned mask 18 covering the semiconductor substrate 10 by using the patterned composite photoresist layer as a mask. While the first nitrogen-containing material layer 16 is etched, the temperature of the wafer stage which the semiconductor substrate 10 is placed on is controlled between 5 and 100 degrees Celsius. Furthermore, the first nitrogen-containing material layer 16 is etched by using an end point control process, the etching time of the end point control process is between 5 and 80 seconds. When etching the oxygen-containing material layer 14, difluoromethane (CH₂F₂) is used as the etchant, and difluoromethane is introduced into an etching reaction chamber where the semiconductor substrate 10 is placed. The flow rate of difluoromethane is between 5 and 100 sccm (standard cubic centimeter per minute). The oxygen-containing material layer 14 is preferably silicon oxide, and the first nitrogen-containing material layer 16 is preferably silicon nitride. Moreover, the first patterned mask 18 includes a first opening 20a, a second opening 20b, a third opening 20c and a fourth opening 20d. Later, the composite photoresist layer is completely removed. Subsequently, a first etching process E1 is performed to etch the semiconductor substrate 10 to form a first trench 22, a second trench 24, a third trench 26 and a fourth trench 28 by using the first patterned mask 18 as a mask. The sidewalls of the first trench 22 are perpendicular to the top surface of the semiconductor substrate 10, and the sidewalls of the second trench 24 are perpendicular to the top surface of the semiconductor substrate 10. The sidewalls of the third trench 26 are perpendicular to the top surface of the semiconductor substrate 10, and the sidewalls of the fourth trench 28 are perpendicular to the top surface of the semiconductor substrate 10.

The operating conditions of the first etching process E1 include a plasma etching process, the operating power of the plasma etching process is between 1000 and 1400 watts, and the transformer coupled capacitive tunable is between 0.1 and 0.5. The first etching process further includes introducing hydrogen bromide (HBr) and nitrogen trifluoride (NF₃) into an etching reaction chamber. A flow rate of hydrogen bromide is between 5 and 500 sccm, and a flow rate of nitrogen trifluoride is between 15 and 25 sccm.

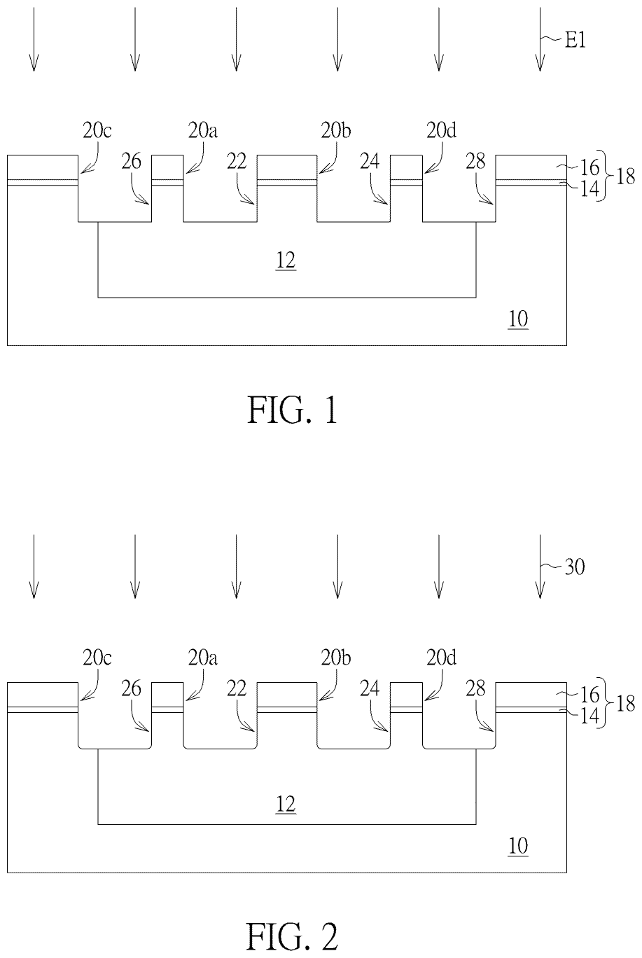

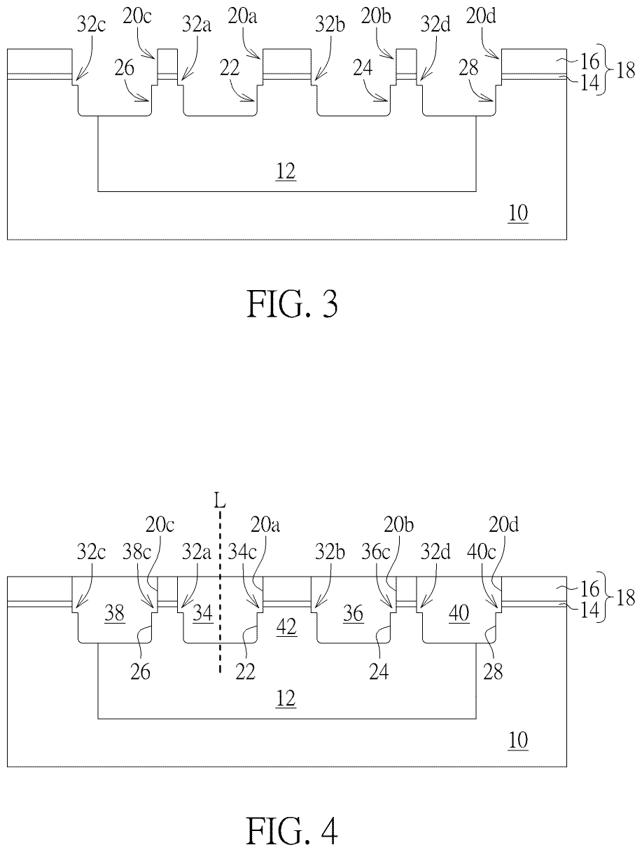

As shown in FIG. 2, a rounding process is performed to make a bottom corner of the first trench 22, a bottom corner of the second trench 24, a bottom corner of the third trench 26 and a bottom corner of the fourth trench 28 rounded. As shown in FIG. 3, the first opening 20a, the second opening 20b, the third opening 20c and the fourth opening 20d on the first patterned mask 18 are widened. While widening the first patterned mask 18, part of the semiconductor substrate 10 is also removed to form corners 32a/32b/32c/32d respectively on the two sidewalls of the first trench 22, the two sidewalls of the second trench 24, the two sidewalls of the third trench 26 and the two sidewalls of the fourth trench 28.

As shown in FIG. 4, a first insulating layer is formed to fill the first trench 22, the second trench 24, the third trench 26, the fourth trench 28, the first opening 20a, the second opening 20b, the third opening 20c and the fourth opening 20d. The first insulating layer filling the first trench 22 and the first opening 20a is defined as a first insulating block 34. The first insulating layer filling the second trench 24 and the second opening 20b is defined as a second insulating block 36. The first insulating layer filling the third trench 26 and the third opening 20c is defined as a first shallow trench isolation 38. The first insulating layer filling the fourth trench 28 and the fourth opening 20d is defined as a second shallow trench isolation 40. The semiconductor substrate 10 disposed between the first insulating block 34 and the second insulating block 36 is defined as a middle substrate 42. Because corners 32a/32b/32c/32d are respectively on the two sidewalls of the first trench 22, the two sidewalls of the second trench 24, the two sidewalls of the third trench 26 and the two sidewalls of the fourth trench 28, after filling the first insulating layer, two protruding portions 34c of the first insulating block 34 are formed on the two sidewalls of the first trench 22 corresponding to the corners 32a. Similarly, two protruding portions 36c of the second insulating block 36 are formed on the two sidewalls of the second trench 24 corresponding to the corners 32b. Two protruding portions 38c of the first shallow trench isolation 38 are formed on the two sidewalls of the third trench 26 corresponding to the corners 32c. Two protruding portions 40c of the second shallow trench isolation 38 are formed on the two sidewalls of the fourth trench 28 corresponding to the corners 32d. The first insulating block 34 has a symmetry axis L perpendicular to the top surface of the semiconductor substrate 10. Taking the symmetry axis L as a reference, the shape of the first insulating block 34 is symmetrical. Similarly, the shape of the second insulating block 36 is symmetrical, the shape of the first shallow trench isolation 38 is symmetrical, and the shape of the second shallow trench isolation 40 is symmetrical.

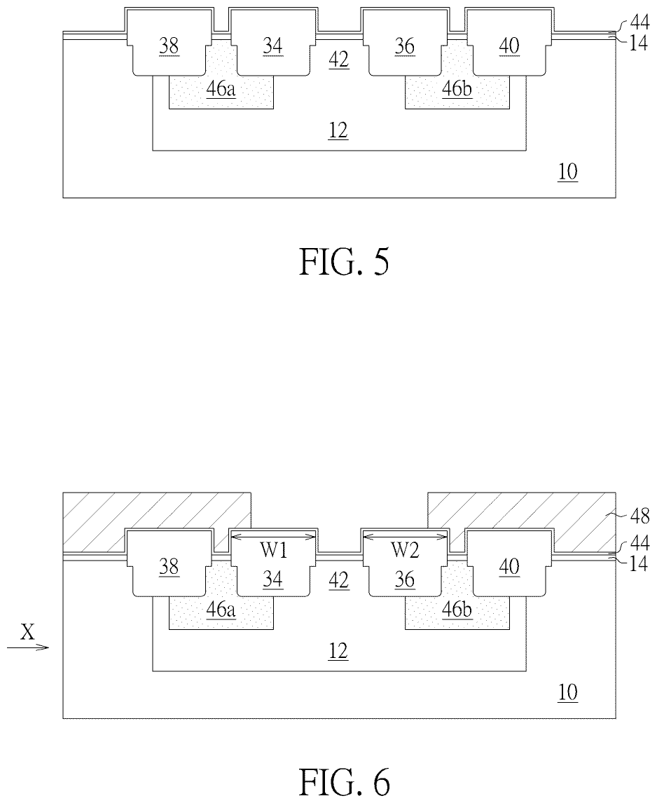

As shown in FIG. 5, the first nitrogen-containing material layer 16 is completely removed to make part of the first insulating block 34, part of the second insulating block 36, part of the third insulating block 38 and part of the fourth insulating block 40 protrude from the oxygen-containing material layer 14. A second nitrogen-containing material layer 44 is then formed to cover the first insulating block 34, the second insulating block 36, the first shallow trench isolation 38, the second shallow trench isolation 40 and the oxygen-containing material layer 14. Next, an ion implantation process is performed to form a first source/drain doping region 46a and a second source/drain doping region 46b. The first source/drain doping region 46a is embedded below the first shallow trench isolation 38, below the first insulating block 34, and in the semiconductor substrate 10 between the first shallow trench isolation 38 and the first insulating block 34. The second source/drain doping region 46b is embedded below the second shallow trench isolation 40, below the second insulating block 36, and in the semiconductor substrate 10 between the second shallow trench isolation 40 and the second insulating block 36. The first source/drain doping region 46a and the second source/drain doping region 46b are of the same conductivity type. The conductive types of the first source/drain doping region 46a and the doping region 12 are different. For example, when the doping region 12 is P-type, the first source/drain doping region 46a and the second source/drain doping region 46b are N-type. When the doping region 12 is N-type, the first source/drain doping region 46a and the second source/drain doping region 46b are P-type.

As shown in FIG. 6, a second patterned mask 48 is formed. The second patterned mask 48 is preferably a photoresist. The second patterned mask 48 only covers the first insulating block 34 which is away from the middle substrate 42, the second insulating block 36 which is away from the middle substrate 42, an entirety of the first shallow trench isolation 38, an entirety of the second shallow trench isolation 40 and part of the semiconductor substrate 10. The second patterned mask 48 does not cover the middle substrate 42 and the first insulating block 34 and the second insulating block 36 adjacent to the middle substrate 42 . According to a preferred embodiment of the present invention, a horizontal direction X parallel to a top surface of the semiconductor substrate 10 is defined. Along the horizontal direction X, the first insulating block 34 includes a first width W1, and the second insulating block 36 includes a second width W2. The second patterned mask 48 only covers no more than one-third of the first width W1, and the second patterned mask 48 only covers no more than one-third of the second width W2.

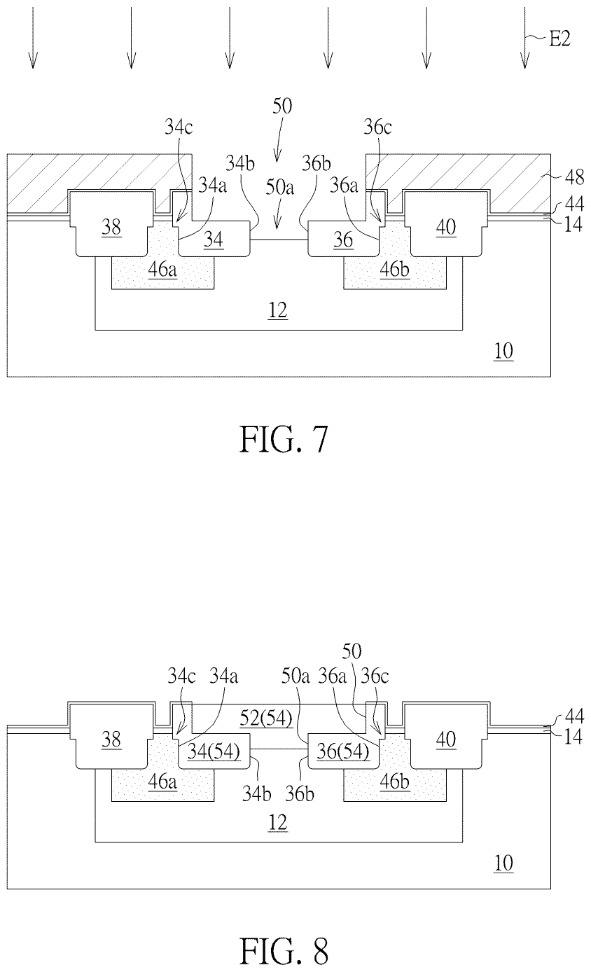

As shown in FIG. 7, a second etching process E2 is performed to etch the first insulating block 34, the second insulating block 36 and the middle substrate 42 to form a fifth trench 50 by using the second patterned mask 48 as a mask. When the middle substrate 42 is etched, the middle substrate 42 is removed conformally along the respective sidewalls of the first insulating block 34 and the second insulating block 36 to make the bottom of the fifth trench 50 is not planar but has a recess 50a. Moreover, the first insulating block 34 is only partially etched. After the second etching process E2 is completed, the sidewall 34b of the first insulating block 34 adjacent to the middle substrate 42 is perpendicular to the top surface of the semiconductor substrate 10, and the protruding portion 34c originally on the sidewall 34b is removed. The protruding portion 34c on the sidewall 34a opposite the sidewall 34b still remains. That is, the protruding portion 34c of the sidewall 34a further away from the middle substrate 42 still remains. Furthermore, the top surface of the first insulating block 34 forms a step profile. Similarly, the sidewall 36b of the second insulating block 36 adjacent to the intermediate substrate 42 is perpendicular to the top surface of the semiconductor substrate 10. The protruding portion 36c on the sidewall 36a further away from the middle substrate 42 still remains. The top surface of the second insulating block 36 forms another step profile. At this time, the shape of the first insulating block 34 is asymmetrical, and the shape of the second insulating block 36 is also asymmetrical.

As shown in FIG. 8, after the second patterned mask 48 is completely removed, a second insulating layer 52 is formed to fill up the fifth trench 50. The second insulating layer 52 is preferably formed by using a thermal oxidation process to form silicon oxide. According to different embodiments, a thermal oxidation process may be performed first followed by performing a deposition process to form silicon oxide. In this embodiment, the second insulating layer 52 fills up the fifth trench 50. However, in other preferred embodiments, the second insulating layer 52 may also fill the fifth trench 50 partially. For example, the second insulating layer 52 can only fill the recess 50a which is formed when the middle substrate 10 is removed during the second etching process E2. The second insulating layer 52, the first insulating block 34 and the second insulating block 36 will together serve as a gate dielectric layer 54 of a high voltage transistor.

As shown in FIG. 8, a gate dielectric layer of a high voltage transistor according to the present invention includes a semiconductor substrate 10. A first insulating block 34 is embedded in the semiconductor substrate 10. A second insulating block 36 is embedded in the semiconductor substrate 10. A second insulating layer 52 is disposed between the first insulating block 34 and the second insulating block 36. The second insulating layer 52 physically directly contacts the first insulating block 34 and the second insulating block 36. The first insulating block 34 has sidewalls 34a/34b. The sidewall 34b physically directly contacts the second insulating layer 52. The sidewall 34a and the sidewall 34b are opposite. The sidewall 34a has a protruding portion 34c. The sidewall 34a and the sidewall 34b are asymmetrical to each other. Moreover, there is no turning point on the sidewall 34b. The shape of the second insulating block 36 is a mirror image of the first insulating block 34. Therefore, the sidewall 36b of the second insulating block 36 physically directly contacts the second insulating layer 52. There is no turning point on the sidewall 36b. The sidewall 36a has a protruding portion 36c. The first insulating block 34 is made of silicon oxide, the second insulating block 36 is made of silicon oxide, and the second insulating layer 52 is made of silicon oxide. Moreover, the bottom corner of the first insulating block 34 is rounded-shaped, and the bottom corner of the second insulating block 36 is also rounded-shaped.

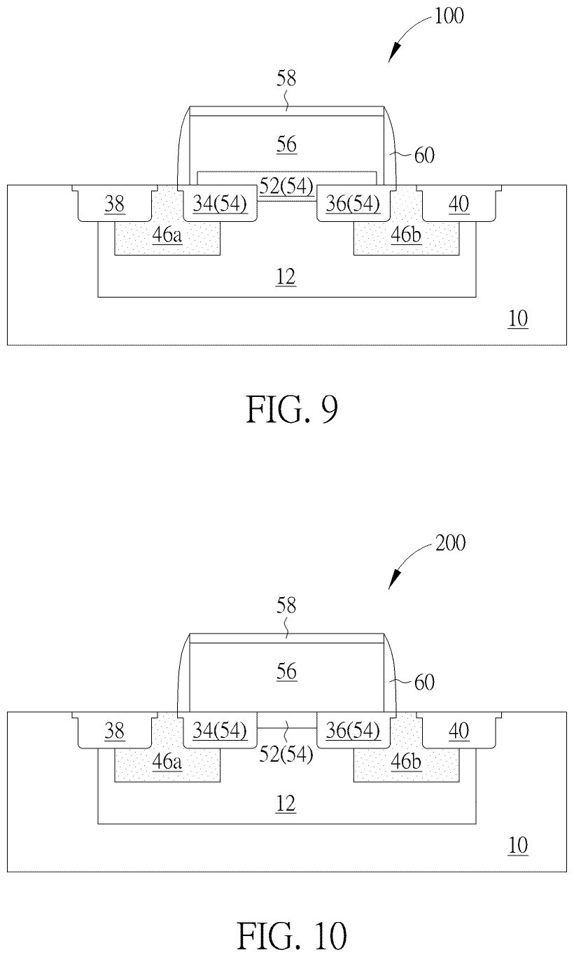

FIG. 9 depicts a fabricating method of a high voltage transistor according to a preferred embodiment of the present invention. FIG. 10 depicts a fabricating method of a high voltage transistor according to another preferred embodiment of the present invention.

Continuing from FIG. 8, as shown in FIG. 9, the second nitrogen-containing material layer 44 and the oxygen-containing material layer 14 are completely removed. Meanwhile, part of the first insulating block 34, part of the second insulating block 36, part of the first shallow trench isolation 38, and part of the second shallow trench isolation 40 are also removed to make the top surface of the remaining first insulating block 34, the top surface of the remaining second insulating block 36, the top surface of the remaining first shallow trench isolation 38 and the top surface of the remaining second shallow trench isolation 40 aligned with the top surface of the semiconductor substrate 10, and lower than the top surface of the second insulating layer 52. Moreover, the top surface of the second insulating layer 52 protrudes from the top surface of the semiconductor substrate 10. After that, a gate electrode 56 is formed directly above the first insulating block 34, the second insulating block 36 and the second insulating layer 52. A cap layer 58 is formed to cover the gate electrode 56. Later, two sidewalls 60 are respectively formed on two sides of the gate electrode 56. The gate electrode 56 is preferably polysilicon. At this point, the high voltage transistor 100 of the present invention is completed. Based on different product requirements, the gate electrode 56 can be replaced by a metal gate later.

The difference between the high voltage transistor in FIG. 10 and the high voltage transistor in FIG. 9 is that in FIG. 10, the top surface of the second insulating layer 52 of the high voltage transistor 200 is aligned with the top surface of the semiconductor substrate 10. The positions of other elements are the same as those in FIG. 9 and are omitted here.

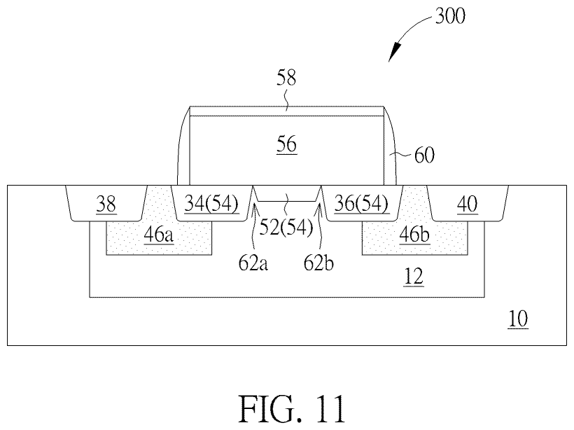

FIG. 11 depicts a high voltage transistor according to an exemplary embodiment of the present invention, wherein elements which are substantially the same as those in the embodiment of FIG. 10 are denoted by the same reference numerals; an accompanying explanation is therefore omitted.

The difference between FIG. 11 and FIG. 10 is that the sidewalls of the first insulating block 34, the sidewalls of the second insulating block 36, the sidewalls of the first shallow trench isolation 38, the sidewalls of the second shallow trench isolation 40 and the sidewalls of the second insulating layer 52 are all sloping edges. In detail, the first insulating block 34, the second insulating block 36, the first shallow trench isolation 38, the second shallow trench isolation 40 and the second insulating layer 52 are respectively of isosceles trapezoid shapes. Therefore, the connected point between the second insulating layer 52 and the first insulating block 34 forms a concave sharp corner 62a. The connected point between the second insulating layer 52 and the second insulating block 36 also forms a concave sharp corner 62b. Therefore, the gate dielectric layer 54 of the high voltage transistor 300 has notches respectively at the sharp corners 62a/62b. The notch causes the breakdown voltage of the high voltage transistor 300 to deviate as temperature changes. Moreover, while replacing the gate electrode by a metal gate, the gate dielectric layer will be damaged more easily duo to the notch.

The first etching process of the present invention specially makes the sidewalls of the first insulating block, the sidewalls of the second insulating block and the sidewalls of the second insulating layer become perpendicular to the top surface of the semiconductor substrate. By doing so, there is no notch formed in the gate dielectric layer. In this way, the deviation of the breakdown voltage can be prevented. The gate dielectric layer can be kept from being damaged when replacing the gate electrode by a metal gate.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fabricating method of a gate dielectric layer of a high voltage transistor, comprising:
providing a semiconductor substrate;
forming a first patterned mask covering the semiconductor substrate, wherein the first patterned mask comprises a first opening and a second opening, the first patterned mask comprises an oxygen-containing material layer and a first nitrogen-containing material layer stacked from bottom to top;
performing a first etching process to etch the semiconductor substrate to form a first trench and a second trench by using the first patterned mask as a mask;
after forming the first trench and the second trench, widening the first opening and the second opening on the first patterned mask;
after widening the first opening and the second opening, forming a first insulating layer to fill the first trench, the second trench, the first opening and the second opening, wherein the first insulating layer filling the first trench and the first opening is defined as a first insulating block, the first insulating layer filling the second trench and the second opening is defined as a second insulating block, and the semiconductor substrate disposed between the first insulating block and the second insulating block is defined as a middle substrate;
completely removing the first nitrogen-containing material layer to make part of the first insulating block and part of the second insulating block protrude from the oxygen-containing material layer;
after removing the first nitrogen-containing material layer, forming a second nitrogen-containing material layer to cover the first insulating block, the second insulating block and the oxygen-containing material layer;
forming a second patterned mask, wherein the second patterned mask only covers the first insulating block which is away from the middle substrate, and the second insulating block which is away from the middle substrate, the second patterned mask covers part of the semiconductor substrate, and the second patterned mask does not cover the middle substrate, the first insulating block which is adjacent to the middle substrate and the second insulating block which is adjacent to the middle substrate;
perform a second etching process to etch the first insulating block, the second insulating block and the middle substrate to form a third trench by using the second patterned mask as a mask;
removing the second patterned mask; and
forming a second insulating layer to fill the third trench.

2. The fabricating method of a gate dielectric layer of a high voltage transistor of claim 1, wherein after forming the third trench, the first insulating block has a top surface, a first sidewall and a second sidewall, the second sidewall contacts the middle substrate, the second sidewall is perpendicular to a top surface of the semiconductor substrate, the first sidewall and the second sidewall are opposite, the first sidewall has a protruding portion, and the top surface of the first insulating block has a step profile.

3. The fabricating method of a gate dielectric layer of a high voltage transistor of claim 1, wherein operating conditions of the first etching process comprise using a plasma etching process, an operating power of the plasma etching process is between 1000 and 1400 watts, a transformer coupled capacitive tunable is between 0.1 and 0.5, and wherein the first etching process further comprises introducing hydrogen bromide (HBr) and nitrogen trifluoride (NF₃) into an etching reaction chamber, and wherein a flow rate of hydrogen bromide is between 5 and 500 sccm (standard cubic centimeter per minute), and a flow rate of nitrogen trifluoride is between 15 and 25 sccm.

4. The fabricating method of a gate dielectric layer of a high voltage transistor of claim 1, wherein when widening the first opening and the second opening on the first patterned mask, part of the semiconductor substrate is also removed to form a corner respectively on a sidewall of the first trench and a sidewall of the second trench.

5. The fabricating method of a gate dielectric layer of a high voltage transistor of claim 1, further comprising after forming the second insulating layer, forming a gate electrode directly on the second insulating layer.

6. The fabricating method of a gate dielectric layer of a high voltage transistor of claim 1, wherein a sidewall of the first trench formed during the first etching process are perpendicular to a top surface of the semiconductor substrate, and a sidewall of the second trench formed during the first etching process are perpendicular to the top surface of the semiconductor substrate.

7. The fabricating method of a gate dielectric layer of a high voltage transistor of claim 1, further comprising after forming the first trench and the second trench and before widening the first opening and the second opening on the first patterned mask, performing a rounding process to make a bottom corner of the first trench rounded and a bottom corner of the second trench rounded.

8. The fabricating method of a gate dielectric layer of a high voltage transistor of claim 1, wherein the first insulating layer is silicon oxide, the second insulating layer is silicon oxide, the first nitrogen-containing material layer is silicon nitride, the second nitrogen-containing material layer is silicon nitride, and the oxygen-containing material layer is silicon oxide.

9. The fabricating method of a gate dielectric layer of a high voltage transistor of claim 1, wherein a horizontal direction is parallel to a top surface of the semiconductor substrate, along the horizontal direction, the first insulating block comprises a first width, and the second insulating block comprises a second width, the second patterned mask only covers no more than one-third of the first width, and the second patterned mask only covers no more than one-third of the second width.

10. A gate dielelctric layer of a high voltage transistor, comprising:
a semiconductor substrate;
a first insulating block embedded in the semiconductor substrate;
a second insulating block embedded in the semiconductor substrate; and
an insulating layer disposed between the first insulating block and the second insulating block, and the insulating layer physically contacting the first insulating block and the second insulating block; wherein:
the first insulating block has a first sidewall and a second sidewall, the second sidewall physically contacts the insulating layer, the first sidewall and the second sidewall are opposite, the first sidewall has a protruding portion, and the first sidewall and the second sidewall are asymmetrical.

11. The gate dielelctric layer of a high voltage transistor of claim 10, wherein there is no turning point on the second sidewall.

12. The gate dielelctric layer of a high voltage transistor of claim 10, further comprising a gate electrode disposed on the first insulating block, the second insulating block and the insulating layer.

13. The gate dielelctric layer of a high voltage transistor of claim 10, wherein a bottom corner of the first insulating block is rounded-shaped, and a bottom corner of the seconed insulating block is rounded-shaped.

14. The gate dielelctric layer of a high voltage transistor of claim 10, wherein the first insulating block is silicon oxide, the second insulating block is silicon oxide, and the insulating layer is silicon oxide.
